(19) United States
(12) Patent Application Publication
(10) Pub. No.: US 2021/0372004 A1
(43) Pub. Date: Dec. 2, 2021

(54) DIAMOND MANUFACTURING APPARATUS, DIAMOND MANUFACTURING METHOD USING THE SAME AND DIAMOND DETECTING METHOD

(71) Applicants: Chih-Shiue YAN, Chiayi County (TW); ALISHAN DIAMOND TECHNOLOGY CORP, New Taipei City (TW)

(72) Inventors: Chih-Shiue YAN, Chiayi County (TW); Cheng-Ming LEE, New Taipei City (TW)

(21) Appl. No.: 17/336,831

(22) Filed: Jun. 2, 2021

Related U.S. Application Data
(60) Provisional application No. 63/033,290, filed on Jun. 2, 2020.

(30) Foreign Application Priority Data
Oct. 23, 2020 (TW) 109136872

(51) Int. Cl. C30B 29/04; C23C 16/27

(52) U.S. Cl. CPC C30B 29/04; G01N 21/64; C23C 16/274; C23C 16/276

(57) ABSTRACT

A diamond manufacturing apparatus for forming at least one diamond is provided. The diamond manufacturing apparatus comprises a growth base and an electric field device. The growth base comprises a top portion and a bottom portion opposite to each other, and the top portion has a growth surface that is concave toward the bottom portion. A plurality of electric field lines of an electric field that is generated by the electric field device are substantially perpendicular to the growth surface.

This application claims the benefit of US provisional application Ser. No. 63/033,290, filed on Jun. 2, 2020 and Taiwan application Serial No. 109136872, filed on Oct. 23, 2020, the disclosure of which are incorporated by reference herein in its entirety.

### BACKGROUND OF THE INVENTION

### Field of the Invention

The invention relates in general to a diamond manufacturing apparatus and more particularly to a diamond manufacturing apparatus that has an improved growth base.

### Description of the Related Art

In general diamond manufacturing apparatus manufactured by plasma chemical vapor deposition (PCVD), the growth area of the base for depositing diamonds is only about 50 mm in diameter at the maximum. In view of this, how to increase the growth area of diamonds is the goal that the skilled in the art wants to achieve.

### SUMMARY OF THE INVENTION

The disclosure is directed to a diamond manufacturing apparatus and a diamond manufacturing method using the same, which can solve the problem in the prior art and increase the growth area of diamonds.

According to a first aspect of the present disclosure, a diamond manufacturing apparatus for forming at least one diamond is provided. The diamond manufacturing apparatus comprises a growth base and an electric field device. The growth base comprises a top portion and a bottom portion opposite to each other, and the top portion has a growth surface that is concave toward the bottom portion. A plurality of electric field lines of an electric field that is generated by the electric field device are substantially perpendicular to the growth surface.

According to a second aspect of the present disclosure, a diamond manufacturing method that uses the diamond manufacturing apparatus according to the first aspect of the present disclosure is provided. The diamond manufacturing method comprises forming at least one diamond on the top portion of the growth base through a microwave plasma chemical vapor deposition (MPCVD).

According to a third aspect of the present disclosure, a diamond detecting method for detecting at least one diamond formed by the diamond manufacturing apparatus according to the first aspect of the present disclosure is provided. The diamond detecting method comprises performing a photoluminescence detection on the at least one diamond, wherein a photoluminescence intensity of a light to excite the at least one diamond presents a broad peak when a wavelength of the light is between 450 nm and 470 nm, and the broad peak is configured to determine whether the at least one diamond has been heat treated.

### BRIEF DESCRIPTION OF THE DRAWINGS

FIG. 1A is a schematic diagram of a diamond manufacturing apparatus according to an embodiment.

FIG. 1B shows a variable implementation of a growth base of a diamond manufacturing apparatus according to an embodiment.

FIG. 1C shows another variable implementation of a growth base of the diamond manufacturing apparatus according to the embodiment.

FIG. 1D shows another variable implementation of a growth base of the diamond manufacturing apparatus according to the embodiment.

FIG. 2 is a schematic diagram of a diamond manufacturing apparatus according to another embodiment.

FIG. 3 is a spectrum diagram corresponding to a photoluminescence performed on a diamond formed by the diamond manufacturing apparatus according to the embodiment.

Common reference numerals are used throughout the drawings and the detailed description to indicate the same elements. The present disclosure will be more apparent from the following detailed description taken in conjunction with the accompanying drawings.

### DETAILED DESCRIPTION OF THE INVENTION

The following description is about the implementation aspects of the present disclosure in detail with reference to the drawings. It should be noted that the structure and content described in the embodiments are for illustrative purposes only, and the protected scope desired by this disclosure is not limited to the described aspects. In the embodiments, the same or similar reference numerals are used to indicate the same or similar parts. It should be noted that this disclosure does not show all possible embodiments. The structure can be changed and modified without departing from the spirit and scope of this disclosure to meet actual requirements of application. Therefore, other possible implementation aspects not mentioned in this disclosure may also be applicable. Furthermore, the drawings have been simplified to clearly illustrate the content of the embodiments, and the size ratios on the drawings are not drawn according to the actual product proportions. Therefore, the contents of the description and drawings are only used to describe the embodiments, not to limit the protected scope desired by this disclosure.

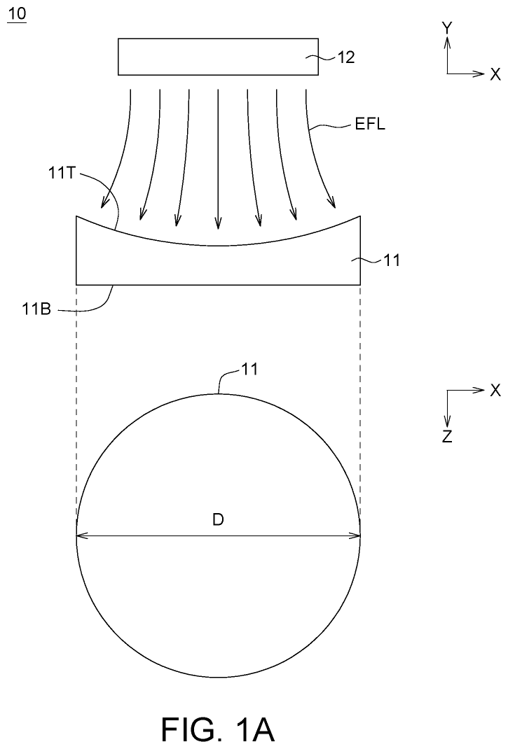

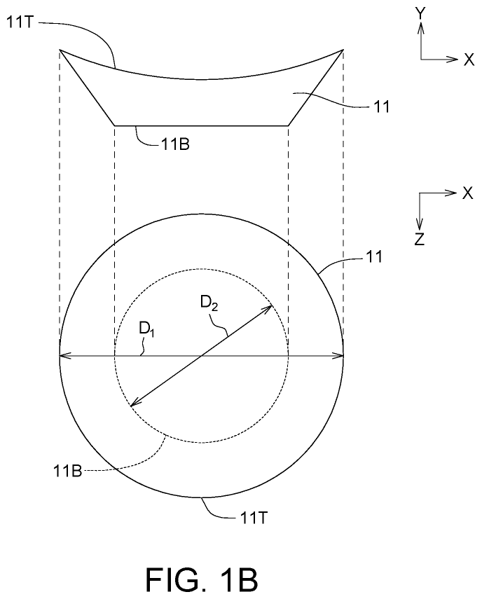

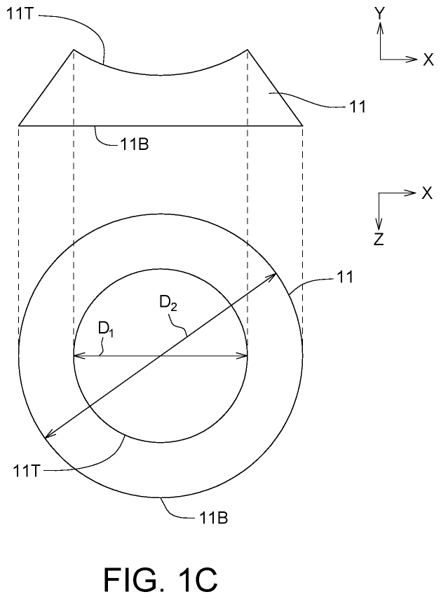

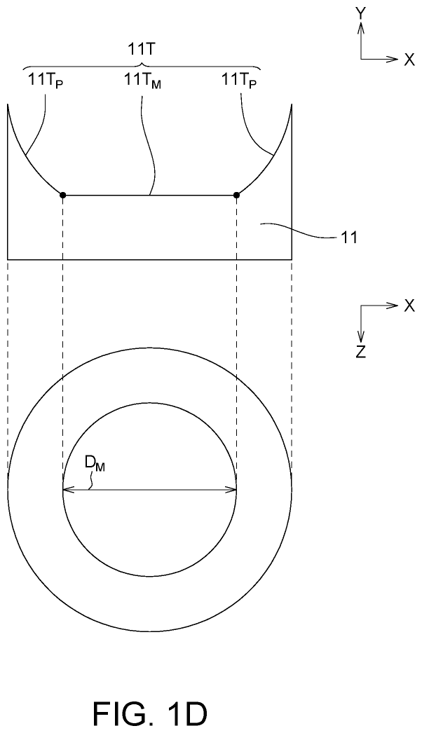

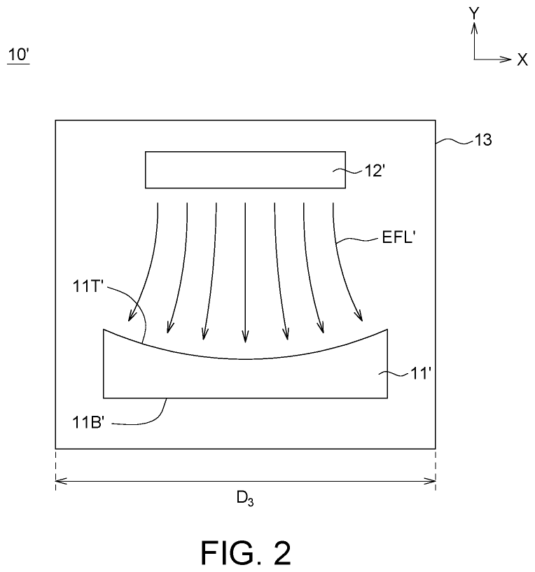

Referring to FIGS. 1 and 2, a display system 100 according to an embodiment is shown therein. Details about the display system 100, a display method applying the same and a display will be described below.

FIG. 1A shows a schematic diagram of a diamond manufacturing apparatus 10 according to an embodiment of the present disclosure.

The diamond manufacturing apparatus 10 is configured to manufacture at least one diamond. The diamond manufacturing apparatus 10 includes a growth base 11 and an electric field device 12. The growth base 11 includes a top portion 11T and a bottom portion 11B, and the top portion 11T and the bottom portion 11B are opposite to each other. As shown in FIG. 1A, the top portion 11T has a growth surface that is concave toward the bottom portion 11B. Regarding its appearance, the growth base 11 looks like a bowl-like structure. The electric field device 12 may be configured to generate an electric field, and a plurality of electric field lines EFL in the electric field are substantially perpendicular to the growth surface of the top portion 11T. It should be noted that the term “substantially perpendicular to” allows an acceptable deviation range, for example, a deviation range of 1% to 2%. Therefore, due to the design that the growth surface is perpendicular to all the electric field lines EFL, the surface area of the top portion 11T of the growth base 11 can be almost completely used for forming diamonds, avoiding waste of surface area of the growth base 11.

The current growth bases used in the prior art to grow diamonds are all flat planes, and it is unable to make an edge of the planar growth base and the electric field lines at the corresponding position be perpendicular, resulting in the formation of black graphite at the edge. (That is, it is not easy to deposit to form diamonds). As such, the effective area of diamond formation is mostly concentrated in the central area of the growth base of the prior art. Compared with the prior art, the diamond manufacturing apparatus in an embodiment of the present disclosure can increase the effective area for forming diamonds by designing the growth base to have a top portion with a growth surface to which the multiple electric field lines in the electric field are substantially perpendicular. According to the experimental results, the production of the diamond manufacturing apparatus of the present disclosure can reach about 60 rough diamonds per month, which is about three times the output compared to the general production of about 20 rough diamonds per month.

Regarding details of the design of the top portion 11T of the growth base 11, from the top view of the Y-axis (longitudinal) in FIG. 1A, the growth surface can be designed to have a circular contour, and a diameter D of the growth surface is between 75 m and 120 mm. In a preferred embodiment, the diameter D of the growth surface of the top portion 11T is about 80 mm.

With regard to details of the design of the bottom portion 11B of the growth base 11, as shown in FIG. 1A, the diameter D of the bottom portion 11B is designed to be substantially equal to that of the top portion 11T. However, the present disclosure is not limited to this. Referring to FIG. 1B and FIG. 1C, which illustrate a variable implementation of the growth base 11 of the present disclosure, the diameter D2 of the bottom portion 11B may be designed to be greater than the diameter Di of the top portion 11T in FIG. 1B; or, the diameter D2 of the bottom portion 11B may be designed to be smaller than that of the top portion 11T in FIG. 1C.

Referring to FIG. 1D, which illustrates another variable implementation of the growth base 11 of the present disclosure. As shown in FIG. 1D, the top portion 11T of the growth base 11 may also comprises a planar surface and a curved surface. In this implementation, a middle portion 11T_{M} of the top portion 11T is a planar surface, and the surrounding portion 11T_{P} of the top portion 11T is a curved surface. The middle portion 11T_{M} may be designed to have a circular contour, and the surrounding portion 11T_{P} may also be designed to have a circular contour. In an embodiment, a diameter DM of the middle portion 11T_{M} is between 45 mm and 55 mm. In a preferred embodiment, the diameter D_{M} of the middle portion 11T_{M} is about 50 mm.

Referring to FIG. 2, it shows a schematic diagram of a diamond manufacturing apparatus 10′ according to another embodiment of the present disclosure.

Similar to the diamond manufacturing apparatus 10 shown in FIG. 1A, the diamond manufacturing apparatus 10′ comprises a growth base 11′ and an electric field device 12′. The growth base 11′ comprises a top portion 11T′ and a bottom portion 11B′, and the top portion 11T′ and the bottom portion 11B′ are opposite to each other. The top portion 11T′ has a growth surface that is concave toward the bottom portion 11B′. Regarding its appearance, the growth base 11′ looks like a bowl-like structure. The electric field device 12′ may be configured to generate an electric field, and a plurality of electric field lines EFL' in the electric field are substantially perpendicular to the growth surface of the top portion 11T′. In addition, as shown in FIG. 2, the diamond manufacturing apparatus 10′ may further comprises a chamber body 13, and the growth base 11′ is disposed in the chamber body 13 such that the process of forming diamonds can be performed in the chamber body 13.

With regard to details of the design of the chamber body 13, in an embodiment, the chamber body 13 may be designed to have a circular inner wall such that a diameter D3 of the chamber body 13 may be designed to be between 150 mm and 250 mm. For example, in a preferred embodiment, the diameter D3 of the chamber body 13 is preferably designed to be about 152.4 mm (6 inches) for an environment where microwaves with a frequency of 2.45 GHz are used.

Similar to the embodiment shown in FIG. 1A, it should be understood that the diamond manufacturing apparatus 10′ can be viewed from the Y-axis (longitudinal) in FIG. 2, and the growth surface of the top portion 11T′ of the growth base 11′ may also be designed to have a circular contour, and a diameter of the growth surface is between 75 mm and 120 mm. In a preferred embodiment, the diameter of the growth surface of the top portion 11T′ is about 80 mm.

In the diamond manufacturing apparatus 10′ shown in FIG. 2 of the present disclosure, the size design for the growth base 11′ and the chamber body 13 may have a corresponding relationship, for example, a relative ratio of a diameter of the growth base 11′ to that of the chamber body 13. Specifically, the ratio of the diameter of the growth surface of the top portion 11T′ to the diameter of the chamber body 13 is greater than or equal to 50%. Similar to the embodiments shown in FIGS. 1B and 10, it should be understood that the bottom portion 11B′ and the top portion 11T′ may also be designed as the variable implementation shown in FIGS. 1B and 1C, so the description will not be repeated here.

Regarding the material selection of the growth base 11 and the growth base 11′ in embodiments of the present disclosure, because a high temperature (for example, the process temperature is between 1000 degrees to 1350 degrees) is a necessary factor for the chemical vapor deposition (CVD) to form diamonds, the growth base 11 and the growth base 11′ may be made of at least one of ceramics (such as silicon, silicon carbide, silicon nitride, boron nitride), refractory metals (such as molybdenum, tungsten), metal carbides, metal nitrides and even diamonds. In a preferred embodiment, the growth base 11 or the growth base 11′ is made of a material including molybdenum.

The diamond manufacturing apparatus described above according to embodiments of the present disclosure can be used in a diamond manufacturing method to form at least one diamond. The diamond manufacturing method of the present disclosure uses a microwave plasma chemical vapor deposition (MPCVD) to form at least one diamond on the top portion of the growth base of the diamond manufacturing apparatus. The microwave plasma chemical vapor deposition uses, for example, a device that can provide microwaves with a frequency of 2.45 GHz or a frequency of 915 MHz.

In an embodiment, the diamond manufacturing method comprises providing an input gas, such as a reactive gas including hydrogen (H2), methane (CH4) and nitrogen (N2), to form diamonds on the growth base. If the concentration of nitrogen (N) to carbon (C) of the input gas is less than 10 ppm, the formed diamond will not cause the Chameleon Effect, which makes diamonds have the color changing characteristic. That is, at least one color-stable diamond is formed. In contrast, if the concentration of nitrogen (N) to carbon (C) of the input gas is higher than 10 ppm, the formed diamond will be able to cause the Chameleon Effect. That is, a color-instable diamond is formed. It can be seen that the input nitrogen (N) relative to the carbon (C) in the diamond manufacturing process is an independent variable that determines whether the diamond has characteristic of the Chameleon Effect or not.

Also, in another embodiment, the diamond manufacturing method further comprises quenching and refining elements from a liquid of a living body or from an environment to be evaporated as sources of the input gas and providing the input gas into the diamond manufacturing apparatus, in order to create specially personal or regionally represented diamonds. For example, the elements may be the composition of carbon, hydrogen, boron, nitrogen or lithium. For example, the liquid of a living body may be sweat, saliva, excretion or blood of a human being. For example, the environment may be water or woods.

As for other control variables in the diamond manufacturing method used in the experiment, the ratio of methane to hydrogen is preferably controlled at about 0.1; and/or the ratio of nitrogen to methane is preferably controlled below about 0.2; and/or the power of the microwave is preferably controlled between 5 kW and 6 kW; and/or the process pressure is preferably controlled between 100 Torr and 250 Torr; and/or the flow rate of hydrogen is preferably controlled to about 400 sccm; and/or the flow rate of methane is preferably controlled to about 30 sccm. Accordingly, the deposition rate (or production rate) of diamonds can be preferably between about 10 μm/h and 40 μm/h, and the size of the formed diamond is about 7 mm in length, 7 mm in width, and about 5 mm in height.

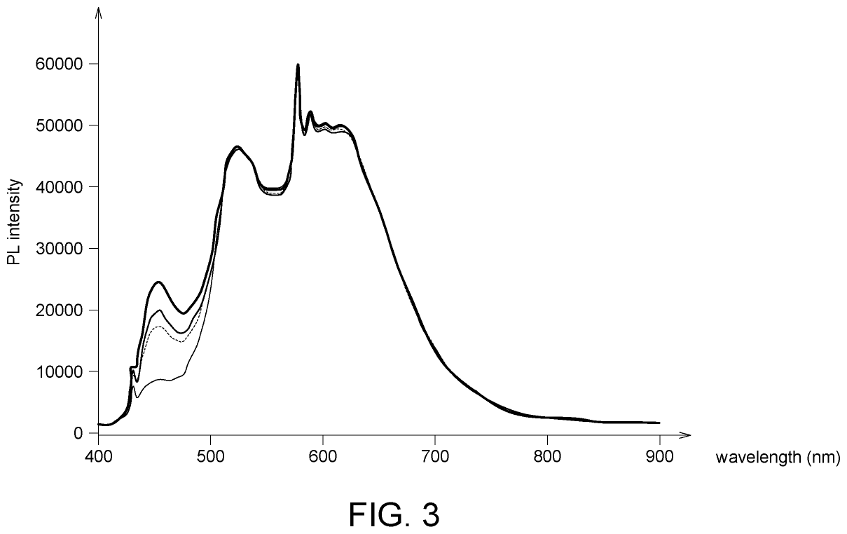

Referring to FIG. 3, it shows a spectrum diagram of corresponding to a photoluminescence performed on a diamond formed by the diamond manufacturing apparatus according to the present disclosure. A laser light with a wavelength of 405 nm is used to perform a photoluminescence (PL) detection on diamonds formed by the diamond manufacturing method according to the present disclosure, and the diamonds are heated to over 800° C. before being exposed to sunlight or ultraviolet light. Then, observe the Raman spectrum of diamond's excited state during the exposure time. As shown in FIG. 3, in the spectrum diagram, at about the wavelength of 430 nm, there is a small peak, which is the first order Raman peak of the Raman spectrum; at about the wavelength of 450 nm to 470 nm, the PL intensity of the light of the excited diamond gradually increases with the exposure time and a broad peak is presented. This broad peak will be apparent after the diamond is heat-treated at a temperature exceeding 1600C. The broad peak can be configured to determine whether diamonds have been heat-treated (especially undergoing an annealing at low pressure high temperature (LPHT) or at high pressure high temperature (HPHT)). Moreover, this broad peak is related to impurities such as nitrogen, hydrogen, and vacancies, which can cause strain and color change of the crystal of diamond. Subsequently, at the wavelength of about 500 nm and more and at the wavelength of about 575 nm where the Neutral Nitrogen Vacancy (NV) happens, the spectrum of the diamond remains the same as the Raman spectrum with the exposure time.

In conclusion, the diamond manufacturing apparatus and the diamond manufacturing method using the same in embodiments of the present disclosure is directed to design the growth base to have a top portion with a growth surface to which the multiple electric field lines in the electric field are substantially perpendicular. Therefore, the effective area for generating diamonds increases, and so the production of diamonds and the diamond deposition rate increase.

While the disclosure has been described and illustrated with reference to specific embodiments thereof, these descriptions and illustrations do not limit the disclosure. It should be understood by those skilled in the art that various changes may be made and equivalents may be substituted without departing from the true spirit and scope of the disclosure as defined by the appended claims. The illustrations may not necessarily be drawn to scale.

There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the disclosure. Accordingly, unless specifically indicated herein, the order and grouping of the operations are not limitations of the disclosure.

What is claimed is:

1. A diamond manufacturing apparatus, comprising:
a growth base including a top portion and a bottom portion opposite to each other, wherein the top portion has a growth surface that is concave toward the bottom portion; and
an electric field device, wherein a plurality of electric field lines in an electric field that is generated by the electric field device are substantially perpendicular to the growth surface.

2. The diamond manufacturing apparatus according to claim 1, wherein the growth surface has a circular contour, and a diameter of the growth surface is between 75 mm and 120 mm.

3. The diamond manufacturing apparatus according to claim 1, wherein a middle part of the growth surface is a flat surface, a surrounding part of the growth surface is a curved surface, the middle part of the growth surface has a circular contour, and a diameter of the middle part is between 45 mm and 55 mm.

4. The diamond manufacturing apparatus according to claim 1, wherein the diamond manufacturing apparatus further comprises a chamber body with a circular inner wall, the growth base is disposed in the chamber body, and a diameter of the chamber body is between 150 mm and 250 mm.

5. The diamond manufacturing apparatus according to claim 1, wherein the growth surface has a circular contour, the diamond manufacturing apparatus further comprises a chamber body with a circular inner wall, the growth base is disposed in the chamber body, and a ratio of a diameter of the growth surface to a diameter of the chamber body is greater than or equal to 50%.

6. The diamond manufacturing apparatus according to claim 1, wherein the growth base is made of a material including molybdenum.

7. A diamond manufacturing method using the diamond manufacturing apparatus according to claim 1, wherein the diamond manufacturing method:
forming at least one diamond on the top portion of the growth base through a microwave plasma chemical vapor deposition (MPCVD).

8. The diamond manufacturing method according to claim 7, wherein the growth surface has a circular contour, and a diameter of the growth surface is between 75 mm and 120 mm.

9. The diamond manufacturing method according to claim 7, wherein a middle part of the growth surface is a flat surface, a surrounding part of the growth surface is a curved surface, the middle part of the growth surface has a circular contour, and a diameter of the middle part is between 45 mm and 55 mm.

10. The diamond manufacturing method according to claim 7, wherein the diamond manufacturing apparatus further comprises a chamber body with a circular inner wall, the growth base is disposed in the chamber body, and a diameter of the chamber body is between 150 mm and 250 mm.

11. The diamond manufacturing method according to claim 7, wherein the growth surface has a circular contour, the diamond manufacturing apparatus further comprises a chamber body with a circular inner wall, the growth base is disposed in the chamber body, and a ratio of a diameter of the growth surface to a diameter of the chamber body is greater than or equal to 50%.

12. The diamond manufacturing method according to claim 7, wherein the growth base is made of a material including molybdenum.

13. The diamond manufacturing method according to claim 7, wherein the step of forming the at least one diamond on the top portion of the growth base through the microwave plasma chemical vapor deposition further comprises:
providing an input gas into the diamond manufacturing apparatus, wherein when the concentration of nitrogen (N) to carbon (C) of the input gas is less than 10 ppm, the at least one diamond is unable to cause the Chameleon Effect.

14. The diamond manufacturing method according to claim 7, wherein the step of forming the at least one diamond on the top portion of the growth base through the microwave plasma chemical vapor deposition further comprises:
providing an input gas into the diamond manufacturing apparatus, wherein when the concentration of nitrogen (N) to carbon (C) of the input gas is higher than 10 ppm, the at least one diamond is able to cause the Chameleon Effect.

15. The diamond manufacturing method according to claim 7, wherein the step of forming the at least one diamond on the top portion of the growth base through the microwave plasma chemical vapor deposition further comprises:
quenching and refining liquid elements from a living body or an environment to be evaporated as sources of an input gas; and
providing the input gas into the diamond manufacturing apparatus.

16. A diamond detecting method for detecting at least one diamond formed by the diamond manufacturing apparatus according to claim 1, wherein the diamond detecting method comprises:
performing a photoluminescence detection on the at least one diamond, wherein a photoluminescence intensity of a light to excite the at least one diamond presents a broad peak when a wavelength of the light is between 450 nm and 470 nm, and the broad peak is configured to determine whether the at least one diamond has been heat treated.
